(19) United States
(12) Patent Application Publication
(10) Pub. No.: US 2026/0282834 A1
(43) Pub. Date: Sep. 17, 2026

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Shun Takagi, Nagano (JP); Hiroshi Ishii, Nagano (JP)

(21) Appl. No.: 19/563,386

(22) Filed: Mar. 11, 2026

(30) Foreign Application Priority Data
Mar. 17, 2025 (JP) 2025-042532

(51) Int. Cl. H10P 72/72; H02N 13/00

(52) U.S. Cl. CPC H10P 72/722; H02N 13/00

(57) ABSTRACT

An electrostatic chuck includes a base body having an upper surface serving as a placement surface for an object to be attracted, an insertion hole formed in the base body and opening to a lower surface of the base, and a columnar ceramic member and a plurality of oxide ceramic particles provided in the insertion hole. The columnar ceramic member has a plurality of holes connecting an upper surface and a lower surface. In plan view, an opening area of each of the holes is smaller than an area of the oxide ceramic particles. Gas can be supplied from the lower surface to the upper surface of the base body via the insertion hole.

### CROSS-REFERENCE TO RELATED APPLICATIONS

This application claims priority from Japanese Patent Application No. 2025-042532, filed on Mar. 17, 2025, the entire content of which is incorporated herein by reference.

### TECHNICAL FIELD

The present invention relates to an electrostatic chuck and a substrate fixing device.

### BACKGROUND ART

In the related art, as a film forming device used when manufacturing a semiconductor device such as an IC or an LSI, for example, a substrate fixing device has been proposed that attracts and clamps a wafer as an object to be attracted by an electrostatic chuck mounted on a base plate. When such a substrate fixing device is used for plasma etching, a discharge may be generated in a gas flow portion provided in the electrostatic chuck during etching processing of a wafer. Therefore, for example, it has been considered to provide a porous portion in the gas flow portion of the electrostatic chuck to take a discharge countermeasure, but a further discharge countermeasure is expected.

### SUMMARY OF INVENTION

The present invention has been made in view of the above points, and an object of the present invention is to further improve discharge resistance in a gas flow portion of an electrostatic chuck.

According to one aspect of the present disclosure, an electrostatic chuck includes a base body having an upper surface serving as a placement surface for an object to be attracted, an insertion hole formed in the base body and opening to a lower surface of the base, and a columnar ceramic member and a plurality of oxide ceramic particles provided in the insertion hole. The columnar ceramic member has a plurality of holes connecting an upper surface and a lower surface. An opening area of each of the holes is smaller than an area of the oxide ceramic particles in plan view. A gas is to be supplied from the lower surface to the upper surface of the base body via the insertion hole.

According to the disclosed technique, it is possible to further improve the discharge resistance in the gas flow portion of the electrostatic chuck.

### BRIEF DESCRIPTION OF DRAWINGS

FIG. 1 is a cross-sectional view illustrating a simplified example of a substrate fixing device according to a first embodiment;

FIGS. 2A and 2B are partially enlarged views of a portion A in FIG. 1;

FIG. 3 is a partially enlarged cross-sectional view of an electrostatic chuck according to a first modification of the first embodiment;

FIG. 4 is a partially enlarged cross-sectional view of an electrostatic chuck according to a second modification of the first embodiment;

FIG. 5 is a partially enlarged cross-sectional view of an electrostatic chuck according to a third modification of the first embodiment;

FIG. 6 is a partially enlarged cross-sectional view of an electrostatic chuck according to a fourth modification of the first embodiment; and

FIG. 7 is a partially enlarged cross-sectional view of an electrostatic chuck according to a fifth modification of the first embodiment.

FIG. 8 is a partially enlarged cross-sectional view of an electrostatic chuck according to a sixth modification of the first embodiment.

FIG. 9 is a partially enlarged cross-sectional view of an electrostatic chuck according to a seventh modification of the first embodiment.

### DESCRIPTION OF EMBODIMENTS

Hereinafter, an embodiment of the present invention will be described with reference to the drawings. In the drawings, the same components are denoted by the same reference signs, and the redundant description thereof may be omitted.

### First Embodiment

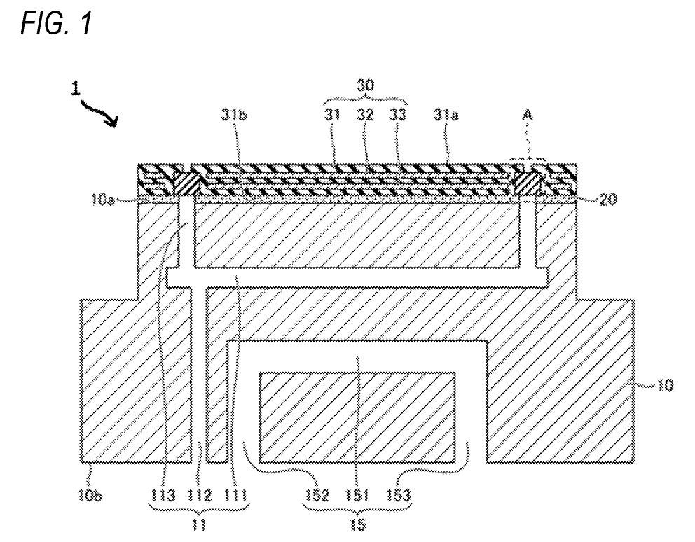

FIG. 1 is a cross-sectional view illustrating a simplified example of a substrate fixing device according to a first embodiment. With reference to FIG. 1, a substrate fixing device 1 includes, as main components, a base plate 10, an adhesive layer 20, and an electrostatic chuck 30.

The base plate 10 is a member on which the electrostatic chuck 30 is mounted. The thickness of the base plate 10 can be, for example, approximately 20 mm or more and 50 mm or less. The base plate 10 can be made of, for example, metal such as aluminum, copper, or titanium. Among these types of metal, it is preferable to use aluminum, which is inexpensive and easy to process.

The base plate 10 can also be used as an electrode or the like for controlling plasma. By supplying a predetermined high frequency power to the base plate 10, it is possible to control the energy for causing generated ions or the like in the plasma state to collide with the wafer attracted on the electrostatic chuck 30, and to effectively perform the etching processing.

A gas supply portion 11 can be provided inside the base plate 10. The gas supply portion 11 includes a gas flow path 111, a gas injection portion 112, and gas discharge portions 113.

The gas flow path 111 is, for example, an annular hole formed inside the base plate 10. The gas injection portion 112 is a hole having one end communicating with the gas flow path 111 and the other end exposed to the outside from a lower surface 10b of the base plate 10, and introduces an inert gas (for example, He or Ar) into the gas flow path 111 from the outside of the substrate fixing device 1. Each gas discharge portion 113 is a hole having one end communicating with the gas flow path 111 and the other end exposed to the outside from the upper surface 10a of the base plate 10 and penetrating the adhesive layer 20, and discharge the inert gas introduced into the gas flow path 111. The gas discharge portions 113 are scattered on the upper surface 10a of the base plate 10 in plan view. The number of gas discharge portions 113 can be appropriately determined as necessary, and is, for example, approximately several tens to several hundreds.

The "plan view" refers to a view of an object from a direction normal to the upper surface 10a of the base plate 10, and the "planar shape" refers to a shape of the object viewed from the direction normal to the upper surface 10a of the base plate 10.

A cooling mechanism 15 can be provided inside the base plate 10. The cooling mechanism 15 includes a refrigerant flow path 151, a refrigerant introduction portion 152, and a refrigerant discharge portion 153. The refrigerant flow path 151 is, for example, an annular hole formed inside the base plate 10. The refrigerant introduction portion 152 is a hole having one end communicating with the refrigerant flow path 151 and the other end exposed to the outside from the lower surface 10b of the base plate 10, and introduces a refrigerant (for example, cooling water or Galden) into the refrigerant flow path 151 from the outside of the substrate fixing device 1. The refrigerant discharge portion 153 is a hole having one end communicating with the refrigerant flow path 151 and the other end exposed to the outside from the lower surface 10b of the base plate 10, and discharges the refrigerant introduced into the refrigerant flow path 151.

The cooling mechanism 15 is connected to a refrigerant control device (not shown) provided outside the substrate fixing device 1. The refrigerant control device (not shown) introduces the refrigerant from the refrigerant introduction portion 152 into the refrigerant flow path 151 and discharges the refrigerant from the refrigerant discharge portion 153. By circulating the refrigerant through the cooling mechanism 15 and cooling the base plate 10, a wafer attracted on the electrostatic chuck 30 can be cooled.

The electrostatic chuck 30 is mounted on the upper surface 10a of the base plate 10 via the adhesive layer 20. As the adhesive layer 20, for example, a silicone resin can be used. The thickness of the adhesive layer 20 is, for example, approximately 0.1 mm to 3.0 mm. The adhesive layer 20 adheres to the base plate 10 and the electrostatic chuck 30, and has an effect of reducing stress caused by a difference in thermal expansion coefficient between the electrostatic chuck 30 made of a ceramic and the base plate 10 made of aluminum.

The thermal conductivity of the adhesive layer 20 is preferably 2 W/mK or more. The adhesive layer 20 may be formed of one layer, and preferably has a two-layer structure in which an adhesive having a high thermal conductivity and an adhesive having a low elastic modulus are combined. Accordingly, an effect of reducing stress caused by a difference in thermal expansion coefficient between the electrostatic chuck 30 made of a ceramic and the base plate 10 made of aluminum and an effect of improving heat dissipation are attained.

The electrostatic chuck 30 is a portion that attracts and clamps a substrate which is an object to be attracted. The planar shape of the electrostatic chuck 30 can be, for example, circular. The diameter of the substrate which is the object to be attracted by the electrostatic chuck 30 can be, for example, approximately 6 inches, 8 inches, 12 inches, or 18 inches. The electrostatic chuck 30 is, for example, a Johnsen-Rahbek type electrostatic chuck. Alternatively, the electrostatic chuck 30 may be a Coulomb force type electrostatic chuck.

The electrostatic chuck 30 includes at least a base body 31, an electrostatic electrode 32, and an RF electrode 33. An upper surface 31a of the base body 31 is a placement surface of the object to be attracted. A plurality of protrusions that come into contact with the object to be attracted such as a silicon wafer may be provided on the upper surface 31a of the base body 31. The base body 31 is a dielectric material, and as the base body 31, for example, ceramics such as aluminum oxide (Al₂O₃) or aluminum nitride (AlN) can be used. The thickness of the base body 31 may be, for example, approximately 1 mm to 10 mm, and the dielectric constant (1 kHz) of the base body 31 may be, for example, approximately 9 to 10.

The electrostatic electrode 32 is a thin film electrode and is provided in the base body 31. The electrostatic electrode 32 is connected to a power source provided outside the substrate fixing device 1, and when a predetermined voltage is applied from the power source, generates an electrostatic attracting force between the electrostatic electrode 32 and the wafer. Accordingly, the wafer can be attracted and held on the upper surface 31a of the base body 31 of the electrostatic chuck 30. An electrostatic attractive force increases as the voltage applied to the electrostatic electrode 32 increases. The electrostatic electrode 32 may have a monopolar shape or a bipolar shape. As the material of the electrostatic electrode 32, for example, tungsten or molybdenum can be used.

The RF electrode 33 is a thin film electrode and is provided in the base body 31. The RF electrode 33 can be provided in, for example, a region excluding the outer peripheral portion of the base body 31. When the substrate fixing device 1 is used for plasma etching, the RF electrode 33 increases the anisotropy of the plasma etching and improves the etching efficiency, and is supplied with a high frequency power for plasma control. The supply of the high frequency power by the RF electrode 33 is used to, for example, efficiently draw plasma when a hole having a high aspect ratio is formed by plasma. The RF electrode 33 is preferably provided in a substantially solid shape in order to uniformly attract plasma.

The electrostatic chuck 30 may include a heating element. The heating element generates heat by applying a voltage from a control circuit provided outside the substrate fixing device 1, and heats the upper surface 31a of the electrostatic chuck 30 to a predetermined temperature. The heating element can heat the upper surface 31a of the electrostatic chuck 30 to approximately 60°C to 300°C, for example. The heating element is, for example, a fired body containing a metal as a main component. The heating element may be a fired body containing a metal as a main component and aluminum oxide. Examples of the metal include tungsten and molybdenum.

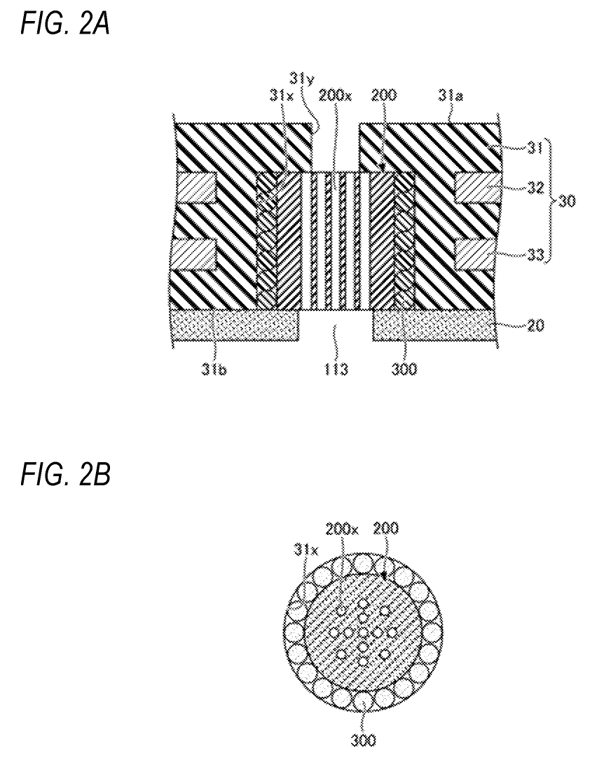

FIGS. 2A and 2B are partially enlarged views of a portion A in FIG. 1, in which FIG. 2A is a cross-sectional view and FIG. 2B is plan view. FIG. 2B illustrates only an insertion hole 31x, a columnar ceramic member 200, holes 200x, and oxide ceramic particles 300.

As shown in FIGS. 2A and 2B, the electrostatic chuck 30 includes an insertion hole 31x formed in the base body 31, and the columnar ceramic member 200 and a plurality of oxide ceramic particles 300 provided in the insertion hole 31x.

The insertion hole 31x opens in the lower surface 31b of the base body 31 and is formed at a position corresponding to each of the gas discharge portions 113 so as to expose the other end of the gas discharge portion 113. Therefore, the insertion hole 31x becomes a part of the gas flow portion, and the gas can be supplied from the lower surface 31b to the upper surface 31a of the base body 31 through the insertion hole 31x. The planar shape of the insertion hole 31x can be, for example, circular. The insertion hole 31x is, for example, a cylindrical cavity. The diameter of the insertion hole 31x can be appropriately determined as necessary, and can be, for example, 1 mm or more and 5 mm or less.

In the illustrated example, the electrostatic chuck 30 has one connection hole 31y communicating with the insertion hole 31x. The insertion hole 31x is connected to the upper surface 31a of the base body 31 via the connection hole 31y. That is, the connection hole 31y is a part of the gas flow portion. The planar shape of the connection hole 31y can be, for example, a circular shape having a diameter smaller than that of the insertion hole 31x. The insertion hole 31x and the connection hole 31y can be arranged concentrically, for example. The insertion hole 31x may be formed so as to penetrate from the upper surface 31a to the lower surface 31b of the base body 31 without forming the connection hole 31y.

The columnar ceramic member 200 is, for example, a columnar member and has a plurality of holes 200x. The columnar ceramic member 200 is, for example, a porous structure plug made of aluminum oxide. As the material of the columnar ceramic member 200, aluminum nitride or the like may be used instead of aluminum oxide. The plurality of holes 200x connect the upper surface and the lower surface of the columnar ceramic member 200. Each of the plurality of holes 200x is, for example, a columnar cavity penetrating from the upper surface to the lower surface of the columnar ceramic member 200. The diameter of the hole 200x can be, for example, 10 μm or more and 90 μm or less.

In the illustrated example, the diameter of the columnar ceramic member 200 is smaller than the diameter of the insertion hole 31x, and a gap is formed between the side surface of the columnar ceramic member 200 and the inner side surface of the insertion hole 31x. The plurality of oxide ceramic particles 300 are formed in the gap. The plurality of oxide ceramic particles 300 include oxide ceramic particles 300 in contact with the side surface of the columnar ceramic member 200. The plurality of oxide ceramic particles 300 include oxide ceramic particles 300 in contact with the inner side surface of the insertion hole 31x.

The oxide ceramic particles 300 are, for example, spherical. In this case, the diameter of the oxide ceramic particle 300 can be, for example, 100 μm or more and 900 μm or less. In plan view, the opening area of each hole 200x of the columnar ceramic member 200 is smaller than the area of the oxide ceramic particle 300. A preferred example of the oxide ceramic particles 300 is spherical aluminum oxide particles. The oxide ceramic particles 300 may be, for example, angular ceramic particles such as coarse-grained alumina.

The electrostatic chuck 30 may have a mixed oxide that adheres to parts of the outer surfaces (the spherical surfaces) of the plurality of oxide ceramic particles 300 and that supports the oxide ceramic particles 300. When the base body 31 is made of aluminum oxide, the mixed oxide can be made of, for example, two or more oxides selected from silicon (Si), magnesium (Mg), calcium (Ca), aluminum (Al), and yttrium (Y).

The columnar ceramic member 200 can be manufactured by, for example, stacking and firing a plurality of green sheets in which holes are formed at predetermined positions. Thereafter, the insertion hole 31x is formed in the base body 31 by machining or the like, and the columnar ceramic member 200 is provided in the insertion hole 31x such that the side surface does not come into contact with the inner side surface of the insertion hole 31x. Then, the oxide ceramic particles 300 are provided between the inner side surface of the insertion hole 31x and the columnar ceramic member 200 together with the paste of the mixed oxide, and fired. Accordingly, the columnar ceramic member 200 and the oxide ceramic particles 300 can be fixed to the insertion hole 31x. The paste of the mixed oxide may further contain an organic binder and a solvent. As the organic binder, for example, polyvinyl butyral can be used. As the solvent, for example, an alcohol can be used. After the columnar ceramic member 200 and the oxide ceramic particles 300 are fixed to the insertion hole 31x, the base body 31 can be machined to form the connection hole 31y communicating with the insertion hole 31x.

In a semiconductor processing process using the electrostatic chuck 30, microfabrication of a semiconductor may be performed by dry etching using plasma, and RF power generated by the RF electrode 33 is often used to generate plasma. In recent years, in order to further improve the efficiency of microfabrication, it is required to increase the density of plasma by increasing the output of RF power. During the process, an object to be attracted such as a silicon wafer is adsorbed on the upper surface 31a of the base body 31, and when the upper surface 31a has a plurality of protrusions, a space between the object to be attracted and the upper surface 31a is filled with gas. The gas reaches the upper surface 31a from the lower surface 31b of the base body 31 through the insertion hole 31x which is the gas flow portion. However, in the gas flow portion having a large diameter, local discharge inside the gas due to an increase in RF power is likely to occur. It is considered that this is because the number of collisions of electrons in the gas increases as the RF power increases in the gas flow portion, and accordingly the discharge probability increases.

Therefore, in the electrostatic chuck 30, the columnar ceramic member 200 and the plurality of oxide ceramic particles 300 are provided in the insertion hole 31x to miniaturize the gas flow portion. Such miniaturization of the gas flow portion can prevent electrons in the gas from being accelerated for a long distance in a predetermined direction. Accordingly, since the number of collisions of electrons in the gas can be reduced, the discharge probability can be reduced. As a result, the discharge resistance in the gas flow portion of the electrostatic chuck 30 can be improved.

The region where the columnar ceramic member 200 having the plurality of holes 200x is provided can form a finer gas flow path than the region where the oxide ceramic particles 300 are provided. Therefore, the columnar ceramic member 200 is preferably provided on at least the same plane as the RF electrode. Accordingly, it is possible to further improve the local discharge resistance in the vicinity of the RF electrode 33. Being provided on the same plane as the RF electrode 33 means that a plane including the upper surface of the RF electrode 33 crosses the columnar ceramic member 200 and a plane including the lower surface of the RF electrode 33 crosses the columnar ceramic member 200.

### Modifications of First Embodiment

In modifications of the first embodiment, a substrate fixing device including an electrostatic chuck in which a configuration in an insertion hole and a configuration of a connection hole are different from those in the first embodiment will be exemplified. In the modifications of the first embodiment, the description of the same components as those of the already described embodiment may be omitted.

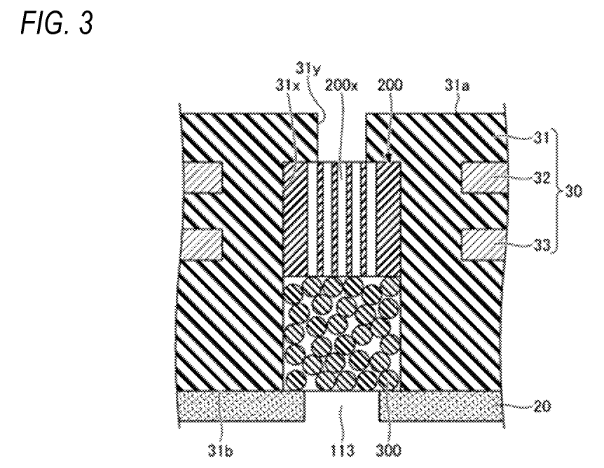

FIG. 3 is a partially enlarged cross-sectional view of an electrostatic chuck according to a first modification of the first embodiment. In the example in FIG. 3, the thickness of the base body 31 is larger than that in the case in FIGS. 2A and 2B, the columnar ceramic member 200 is provided on the upper side of the insertion hole 31x, and the plurality of oxide ceramic particles 300 are provided on the lower side. The side surface of the columnar ceramic member 200 is in contact with the inner side surface of the insertion hole 31x. The side surface of the columnar ceramic member 200 may be in contact with the inner side surface of the insertion hole 31x via a bonding material. The plurality of oxide ceramic particles 300 include oxide ceramic particles in contact with the lower surface of the columnar ceramic member 200.

When the length of the columnar ceramic member 200 increases, it is difficult to stably form the fine holes 200x. Therefore, when the base body 31 is relatively thick, as shown in FIG. 3, it is preferable to provide the columnar ceramic member 200 on the upper side of the insertion hole 31x and provide the plurality of oxide ceramic particles 300 on the lower side. Accordingly, since the length of the columnar ceramic member 200 can be made relatively small, the fine holes 200x can be stably formed. Since the columnar ceramic member 200 can be provided on at least the same plane as the RF electrode, the local discharge resistance in the vicinity of the RF electrode 33 can be further improved.

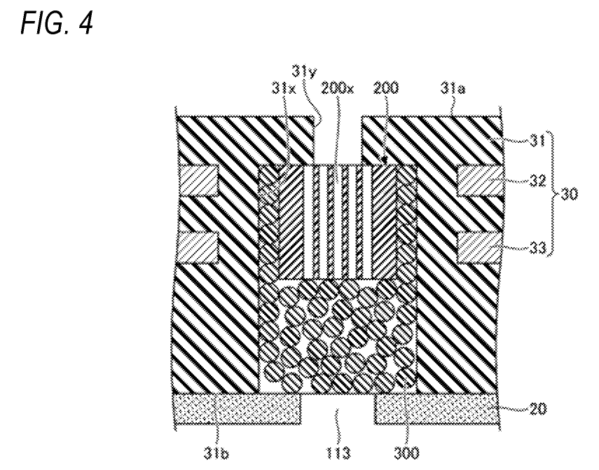

FIG. 4 is a partially enlarged cross-sectional view of an electrostatic chuck according to a second modification of the first embodiment. In the example in FIG. 4, in addition to the configuration in FIG. 3, a gap is formed between the columnar ceramic member 200 and the inner side surface of the insertion hole 31x, and the oxide ceramic particles 300 are provided in the gap. That is, the plurality of oxide ceramic particles 300 include the oxide ceramic particles 300 in contact with the side surface of the columnar ceramic member 200 and the oxide ceramic particles 300 in contact with the lower surface of the columnar ceramic member 200. In this case, the same effect as in the case in FIG. 3 is attained.

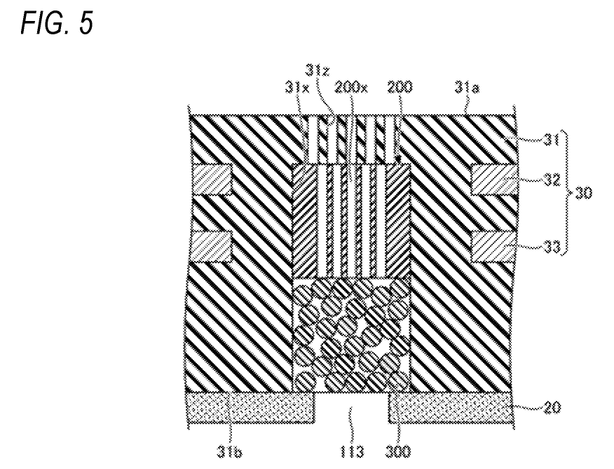

FIG. 5 is a partially enlarged cross-sectional view of an electrostatic chuck according to a third modification of the first embodiment. The example in FIG. 5 is different from the example in FIG. 3 in that the insertion hole 31x is connected to the upper surface 31a of the base body 31 via a plurality of connection holes 31z communicating with the insertion hole 31x. Each of the connection holes 31z is, for example, a cylindrical cavity. The diameter of the connection hole 31z can be, for example, 10 μm or more and 90 μm or less. For example, the connection holes 31z may be formed at positions corresponding to the holes 200x in plan view, or may be formed in any other arrangement.

In the structure shown in FIG. 5, by forming the plurality of fine connection holes 31z in the base body 31 located above the columnar ceramic member 200, it is possible to further reduce long-distance acceleration of electrons in the gas. Accordingly, since the number of collisions of electrons in the gas can be further reduced, the discharge probability can be further reduced. As a result, the discharge resistance in the gas flow portion of the electrostatic chuck 30 can be further improved.

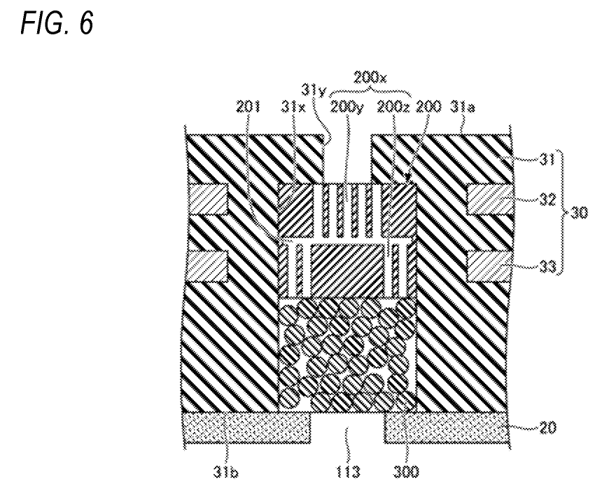

FIG. 6 is a partially enlarged cross-sectional view of an electrostatic chuck according to a fourth modification of the first embodiment. The example in FIG. 6 is different from the example in FIG. 3 in that the columnar ceramic member 200 includes a space 201 larger than the area of the oxide ceramic particles 300 in plan view. The example in FIG. 4 is different from the example in FIG. 3 in that the plurality of holes 200x include a first hole 200y connecting the space 201 and the upper surface of the columnar ceramic member 200 and a second hole 200z connecting the space 201 and the lower surface of the columnar ceramic member 200. The space 201 may have, for example, a relatively thin columnar shape. The thickness of the space 201 may be, for example, 10 μm or more and 90 μm or less. The first hole 200y and the second hole 200z are preferably formed at positions not overlapping each other in plan view.

In the structure shown in FIG. 6, by forming the space 201, it is possible to further reduce the long-distance acceleration of electrons in the gas. Accordingly, since the number of collisions of electrons in the gas can be further reduced, the discharge probability can be further reduced. As a result, the discharge resistance in the gas flow portion of the electrostatic chuck 30 can be further improved.

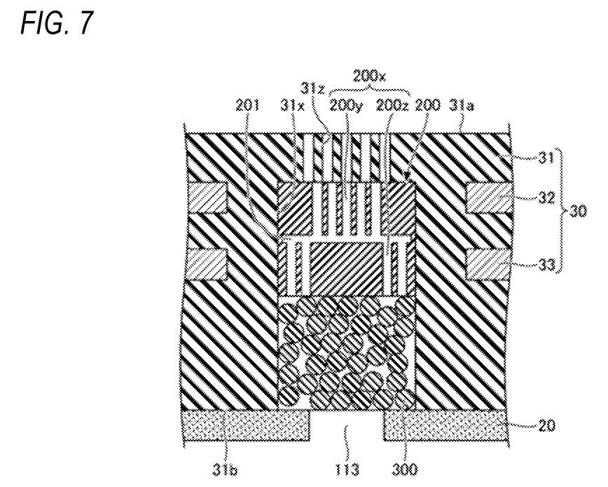

FIG. 7 is a partially enlarged cross-sectional view of an electrostatic chuck according to a fifth modification of the first embodiment. The example in FIG. 7 is different from the example in FIG. 6 in that the insertion hole 31x is connected to the upper surface 31a of the base body 31 via the plurality of connection holes 31z communicating with the insertion hole 31x. That is, since the structure shown in FIG. 7 is a combination of the structure shown in FIG. 5 and the structure shown in FIG. 6, the discharge probability can be further reduced as compared with the structure shown in FIGS. 5 and 6, and the discharge resistance in the gas flow portion of the electrostatic chuck 30 can be further improved.

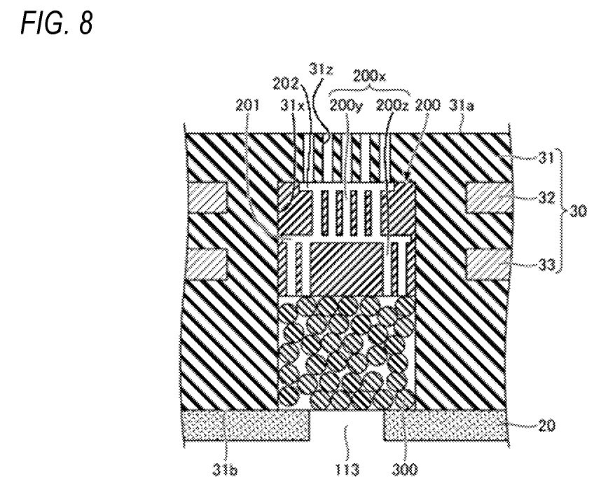

FIG. 8 is a partially enlarged cross-sectional view of an electrostatic chuck according to a sixth modification of the first embodiment. The example in FIG. 8 differs from FIG. 7 in that an additional space 202 is provided at an upper part of the columnar ceramic member 200. The space 202 may have, for example, a relatively thin columnar shape. The thickness of the space 202 may be, for example, 10 μm or more and 90 μm or less. By providing such a space 202, a first hole 200y of the columnar ceramic member 200 disposed on an upper side of the insertion hole 31x of the base body 31 and a connection hole 31z of the base body 31 can be more reliably brought into communication. Accordingly, the gas flow rate in the gas flow portion of the electrostatic chuck 30 can be reliably ensured.

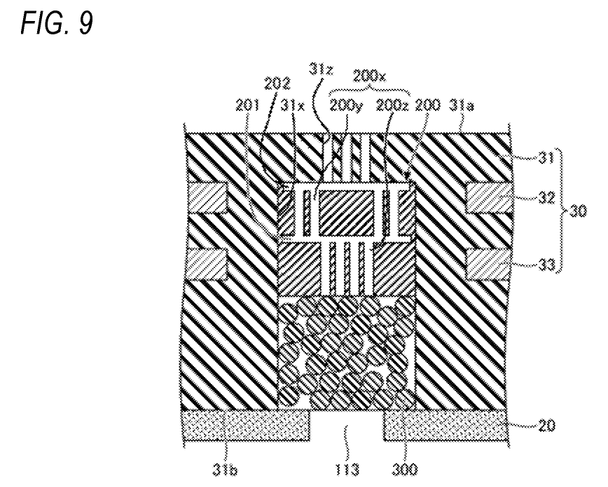

FIG. 9 is a partially enlarged cross-sectional view of an electrostatic chuck according to a seventh modification of the first embodiment. The example in FIG. 9 differs from FIG. 8 in that the connection hole 31z of the base body 31 is formed so as to communicate only with a vicinity of a central portion on an upper side of the insertion hole 31x. In the example in FIG. 9, the first hole 200y of the columnar ceramic member 200 is formed so as to communicate, in plan view, only with vicinities of the outer edge portions of the space 201 and the space 202, and the space 201 and the second hole 200z of the columnar ceramic member 200 are formed so that, in plan view, they communicate only with vicinities of a central portion of the space 201 and of a central portion of the lower surface of the columnar ceramic member 200. Therefore, in the example in FIG. 9, in plan view, the connection hole 31z of the base body 31 and the first hole 200y of the columnar ceramic member 200 do not overlap, and the first hole 200y and the second hole 200z of the columnar ceramic member 200 also do not overlap. By arranging the connection hole 31z and the first hole 200y and the second hole 200z as in FIG. 9, the flow path in the gas flow portion becomes longer, and therefore the discharge probability can be reduced.

Although the preferred embodiment and the like have been described in detail, the present invention is not limited to the embodiment and the like described above, and various modifications and substitutions can be made to the embodiment and the like described above without departing from the scope of the claims.

What is claimed is:

1. An electrostatic chuck comprising:
a base body having an upper surface serving as a placement surface for an object to be attracted;
an insertion hole formed in the base body and opening to a lower surface of the base body; and
a columnar ceramic member and a plurality of oxide ceramic particles provided in the insertion hole,
wherein the columnar ceramic member has a plurality of holes connecting an upper surface and a lower surface,
wherein an opening area of each of the holes is smaller than an area of the oxide ceramic particles in plan view, and
wherein a gas is to be supplied from the lower surface to the upper surface of the base body via the insertion hole.

2. The electrostatic chuck according to claim 1,
wherein the plurality of oxide ceramic particles include the oxide ceramic particles in contact with a side surface of the columnar ceramic member.

3. The electrostatic chuck according to claim 1,
wherein the plurality of oxide ceramic particles include the oxide ceramic particles in contact with the lower surface of the columnar ceramic member.

4. The electrostatic chuck according to claim 1,
wherein the plurality of oxide ceramic particles include the oxide ceramic particles in contact with a side surface of the columnar ceramic member and the oxide ceramic particles in contact with the lower surface of the columnar ceramic member.

5. The electrostatic chuck according to claim 1,
wherein the insertion hole is connected to the upper surface of the base body via one connection hole communicating with the insertion hole.

6. The electrostatic chuck according to claim 1,
wherein the insertion hole is connected to the upper surface of the base body via a plurality of connection holes communicating with the insertion hole.

7. The electrostatic chuck according to claim 1
wherein the columnar ceramic member has a space larger than the area of the oxide ceramic particles in plan view, and
wherein the plurality of holes include a first hole connecting the space and the upper surface of the columnar ceramic member and a second hole connecting the space and the lower surface of the columnar ceramic member.

8. The electrostatic chuck according to claim 1,
wherein each of the plurality of holes penetrates from the upper surface to the lower surface of the columnar ceramic member.

9. The electrostatic chuck according to claim 1, further comprising
an RF electrode embedded in the base body,
wherein the columnar ceramic member is provided on at least the same plane as the RF electrode.

10. The electrostatic chuck according to claim 1,
wherein a diameter of the hole is 10 μm or more and 90 μm or less.

11. A substrate fixing device comprising:
a base plate including a gas supply portion therein; and
the electrostatic chuck according to claim 1 provided on the base plate,
wherein a gas is supplied from the gas supply portion to the upper surface of the base body through the insertion hole.
